(19) United States
(12) Patent Application Publication
(10) Pub. No.: US 2014/0175619 A1
(43) Pub. Date: Jun. 26, 2014

(54) STRIPLINE AND REFERENCE PLANE IMPLEMENTATION FOR INTERPOSERS USING AN IMPLANT LAYER

(71) Applicant: NVIDIA CORPORATION, Santa Clara, CA (US)

(72) Inventors: Abraham F. Yee, Cupertino, CA (US); Mayan Riat, Sunnyvale, CA (US)

(73) Assignee: NVIDIA CORPORATION, Santa Clara, CA (US)

(21) Appl. No.: 13/722,334

(22) Filed: Dec. 20, 2012

(51) Int. Cl. H01L 23/60

(52) U.S. Cl. CPC H01L 23/60
USPC 257/655

(57) ABSTRACT

An integrated circuit system includes an interposer substrate with an electrical reference plane, or “ground plane,” formed by a conductive semiconductor layer. The conductive semiconductor layer may be formed in a surface region of the interposer substrate, and in some embodiments is formed by performing an ion implant process on the surface region to increase the electrical conductivity of the surface region. Because the surface region is electrically coupled to an electrical ground of the integrated circuit system, the surface region functions as a ground plane that helps contain electric fields produced by signals routed through interconnects of the interposer substrate. Consequently, a ground plane can be formed on a surface of the interposer substrate without forming a metalization layer.

### BACKGROUND OF THE INVENTION

1. Field of the Invention

Embodiments of the present invention relate generally to integrated circuit chip packaging and, more specifically, to an interposer substrate with an electrical reference plane formed by a conductive semiconductor layer.

2. Description of the Related Art

In the packaging of integrated circuit (IC) chips, one or more IC chips are commonly mounted on an interposer substrate. The interposer substrate is a component of the chip package and is designed to route power, signal, and ground interconnects between IC chips in the chip package to external electrical connections, such as a ball-grid array, for connecting the packaged IC chip to a printed circuit board. To this end, an interposer substrate typically includes electrically conductive traces formed in one or more layers on a surface of the interposer substrate.

To improve signal-to-noise ratio of signals routed via these electrically conductive traces, electrically conductive ground planes disposed above and below the conductive traces can be used to form what is essentially a Faraday cage that contains electric fields produced by the routed signals. The formation of such ground planes is problematic, however, in that each ground plane formed on an interposer substrate requires the formation of an additional electrically conductive metal layer, adding cost and manufacturing complexity to the interposer substrate.

Accordingly, there is a need in the art for an interposer substrate design that includes relatively fewer metallic ground planes.

### SUMMARY OF THE INVENTION

One embodiment of the present invention sets forth an semiconductor-based system that includes an interposer substrate and at least one semiconductor die mounted on the interposer substrate. In this embodiment, the interposer substrate includes a bulk region of a first semiconductor type that is doped with a dopant, a surface region of the first semiconductor type that is formed on the bulk region and is more heavily doped than the bulk region, an electrical interconnect layer formed on the surface region, and a ground plane that is formed on the electrical interconnect layer and is electrically coupled to the surface region.

One advantage of the above-described embodiment is that a ground plane can be formed on a surface of an interposer substrate without forming a metalization layer, thereby greatly simplifying fabrication and reducing the cost of the interposer substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic perspective view of an integrated circuit system, according to one embodiment of the invention.

FIG. 2 is a schematic cross-sectional view of the IC system in FIG. 1, taken at section A-A in FIG. 1.

FIGS. 3A-3F sequentially illustrate cross-sectional views of the integrated circuit system in FIG. 1 in various stages of fabrication, according to embodiments of the invention.

FIG. 4 schematically illustrates a plan view of an IC system, according to one embodiment of the invention.

FIG. 5 illustrates a computing device in which one or more embodiments of the present invention can be implemented.

For clarity, identical reference numbers have been used, where applicable, to designate identical elements that are common between figures. It is contemplated that features of one embodiment may be incorporated in other embodiments without further recitation.

### DETAILED DESCRIPTION

One embodiment of the present invention sets forth an integrated circuit system that includes an interposer substrate with an electrical reference plane, or “ground plane,” formed by a conductive semiconductor layer. The conductive semiconductor layer may be formed in a surface region of the interposer substrate, and in some embodiments is formed by performing an ion implant process on the surface region to increase the electrical conductivity of the surface region. Because the surface region is electrically coupled to an electrical ground of the integrated circuit system, the surface region is a ground plane that helps contain electric fields produced by signals routed through interconnects of the interposer substrate. Consequently, a ground plane can be formed on a surface of the interposer substrate without forming a metalization layer.

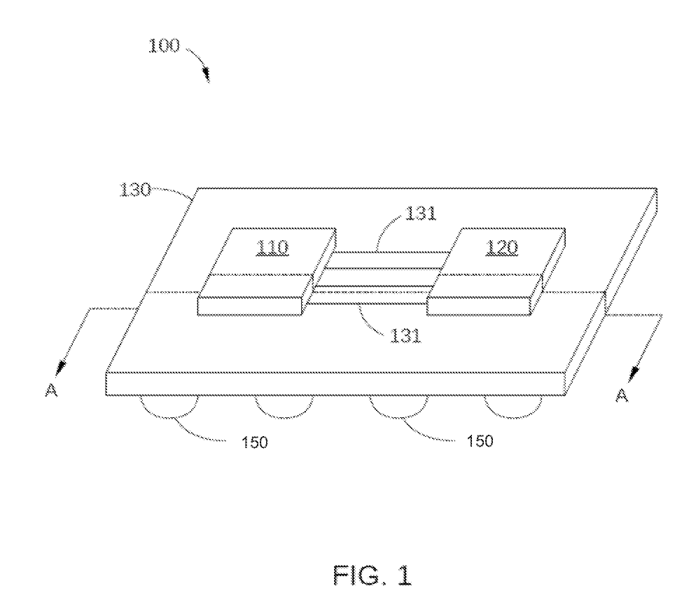

FIG. 1 is a schematic perspective view of an integrated circuit (IC) system 100, according to one embodiment of the invention. IC system 100 comprises a chip package that includes a first IC 110, a second IC 120, an interposer substrate 130, and packaging leads 150. IC system 100 is generally configured to electrically and mechanically connect first IC 110, second IC 120, and any other logic or memory ICs mounted on interposer substrate 130 to a printed circuit board or other mounting substrate (not shown) external to IC system 100. For clarity, some elements of IC system 100 are omitted from FIG. 1, such as overmolding and a heat spreader.

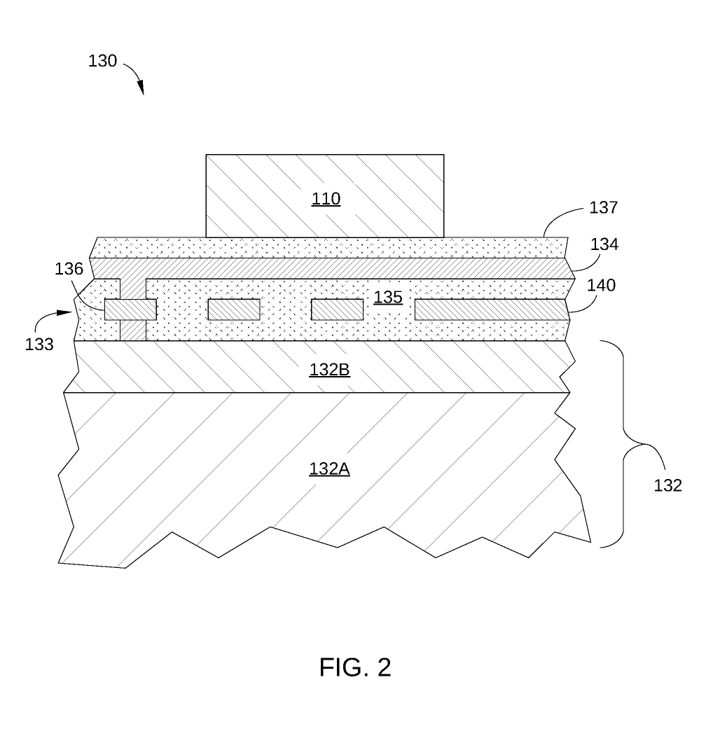

First IC 110 and second IC 120 each comprise a semiconductor chip, such as a central processing unit (CPU), a graphics processing unit (GPU), an application processor or other logic device, a memory chip, a global positioning system (GPS) chip, a radio frequency (RF) transceiver chip, a Wi-Fi chip or any semiconductor chip that is suitable for mounting on interposer substrate 130. In some embodiments, first IC 110 is a logic chip and second IC 120 is a memory chip associated with first IC 110. In other embodiments, first IC 110 and second IC 120 are both logic chips. First IC 110 and second IC 120 are mounted on interposer substrate 130, and are electrically coupled to each other via interconnects 131 formed on interposer substrate 130. Due to the high data input/output speeds associated with modern ICs, disposing interconnects 131 between ground planes formed on interposer substrate 130 can greatly improve the signal-to-noise ratio of signals carried by interconnects 131. Ground planes on interposer substrate 130 formed according to one or more embodiments of the invention are described below in conjunction with FIG. 2.

Interposer substrate 130 comprises an intermediate layer or structure that provides electrical connections between first IC 110, second IC 120, and other semiconductor chips mounted thereon, and to packaging leads 150. In some embodiments, interposer substrate 130 is formed from a semiconductor substrate and is configured with multiple layers of interconnects and vias to provide such electrical connections. In some embodiments, interposer 130 includes through-silicon vias to provide very short electrical connections between semiconductor chips mounted on interposer substrate 130 and packaging leads 150, thereby facilitating high-speed propagation of signals between such semiconductor chips and packaging leads 150. Interposer 130 is described in greater detail below in conjunction with FIG. 2.

Packaging leads 150 provide electrical connections between IC system 100 and a mounting substrate external to IC system 100, such as a printed circuit board. Packaging leads 150 may include any technically feasible chip package electrical connection known in the art, including a ball-grid array (BGA), a pin-grid array (PGA), and the like.

FIG. 2 is a schematic cross-sectional view of IC system 100, taken at section A-A in FIG. 1. As shown, interposer substrate 130 includes a semiconductor substrate 132, a signal layer 133, a ground plane 134, electrically insulating layers 135, a contact structure 136, a passivation layer 137, and signal interconnects 140. First IC 110 is mounted on interposer substrate 130 and is electrically coupled to ground plane 134 and one or more of signal interconnects 140. First IC 110 may be mounted to interposer substrate 130 using solder microbumps or any other technically feasible approach, but for clarity, such mounting and electrical connections are omitted from FIG. 2. Furthermore, interposer substrate 130 may include multiple signal layers 133, but in FIG. 2 only a single signal layer 133 is shown.

Semiconductor substrate 132 comprises a semiconductor material of a single semiconductor type, and includes a bulk region 132A that is lightly doped and a surface region 132B that is more heavily doped. In some embodiments, semiconductor substrate 132 comprises a P-type material, which is generally the most common semiconductor type used for interposer substrates. In other embodiments, semiconductor substrate 132 comprises an N-type material. Bulk region 132A can be a very lightly doped material, for example having a doping ion concentration of 10E10 to 10E13 ions/cm³ and an electrical resistivity that is between about 5 ohm-cm and about 100 ohm-cm. Lower resistivity than about 5 or 6 ohm-cm can cause unwanted coupling between components mounted on interposer substrate 130, and is highly undesirable. Suitable dopant ions include boron difluoride (BF₂) and boron (B), among others.

Surface region 132B comprises a region on the surface of semiconductor substrate 132 on which signal layer 133, ground plane 134, and electrically insulating layers 135 are formed. To form one of the two ground planes between which signal layer 133 is disposed, surface region 132B comprises a relatively highly doped semiconductor material. For example, in some embodiments, surface region 132B is doped with one or more dopants sufficient for surface region 132B to have a doping ion concentration of 10E14 to 10E16 ions/cm³ and a sheet resistance that is no greater than about 100-200 ohm/sq. With such low resistivity, surface region 132B has enough electrical conductivity to form a ground plane when coupled to ground. Consequently, the formation of a metalization layer between signal layer 133 and bulk region 132A is not required for efficient transmission of signals in signal layer 133. In some embodiments, surface region 132B is formed using an ion implantation process on semiconductor substrate 132, in which dopant ions are implanted to a desired depth and at a desired concentration to form surface region 132B on top of bulk region 132A. In other embodiments, surface region 132B may be formed by a deposition process on a surface of bulk region 132A. In either case, suitable dopants include boron difluoride and boron, among others.

Signal layer 133 is formed between surface region 132B and ground plane 134, and includes signal interconnects 140. Signal interconnects 140 are routed through electrically insulating layers 135 to electrically connect first IC 110 and second IC 120 as desired. For example, signal interconnects 140 may include interconnects 131 in FIG. 1. In addition, signal interconnects 140 may connect first IC 110 and second IC 120 to packaging leads 150, using through-silicon vias or other features in semiconductor substrate 132. Generally, signal interconnects 140 may be electrically coupled to contacts on first IC 110 and through-silicon vias formed in semiconductor substrate 132, but such features are omitted from FIG. 2 for clarity.

Ground plane 134 comprises an electrically conductive layer formed on an outer surface of interposer substrate 130 so that signal interconnects 140 are disposed between ground plane 134 and surface region 132B. In some embodiments, ground plane 134 comprises a metallic layer deposited as shown in FIG. 2, such as a copper (Cu) or aluminum (Al) layer. Electrically insulating layers 135 are formed around signal interconnects 140, so that ground plane 134 and surface region 132B are electrically isolated from signal interconnects 140 and so that signal interconnects 140 are electrically isolated from each other. Passivation layer 137 is formed on an outer surface of ground plane 134, and one or more contact structures 136 are formed in electrically insulating layers 135, so that ground plane 134 and surface region 132B are electrically coupled to each other. In some embodiments, bulk region 132A is connected to electrical ground. Consequently, in such embodiments, surface region 132B and ground plane 134 are also electrically connected to ground.

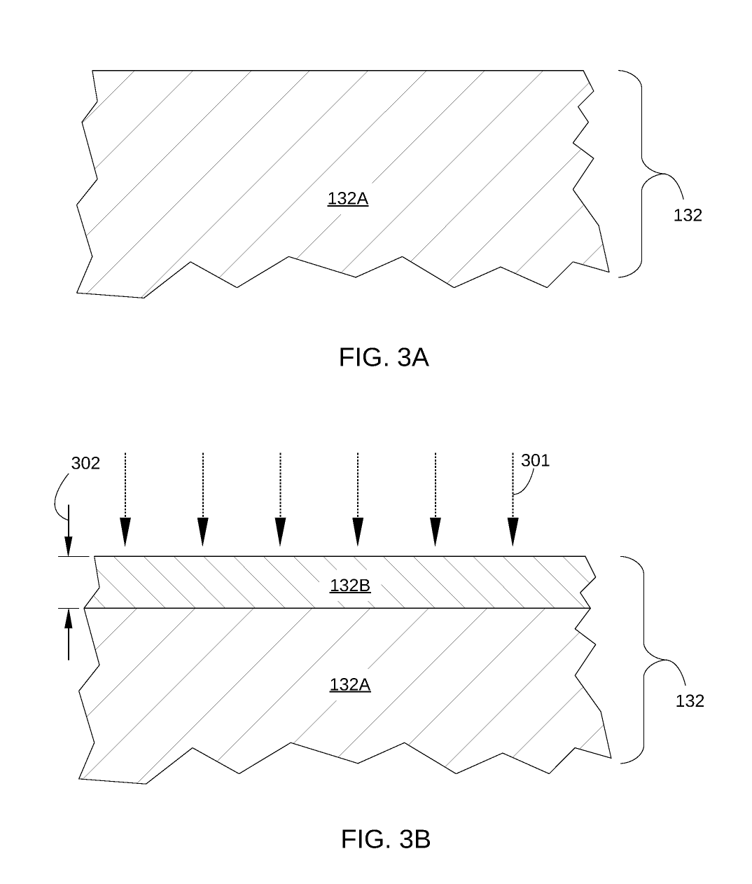

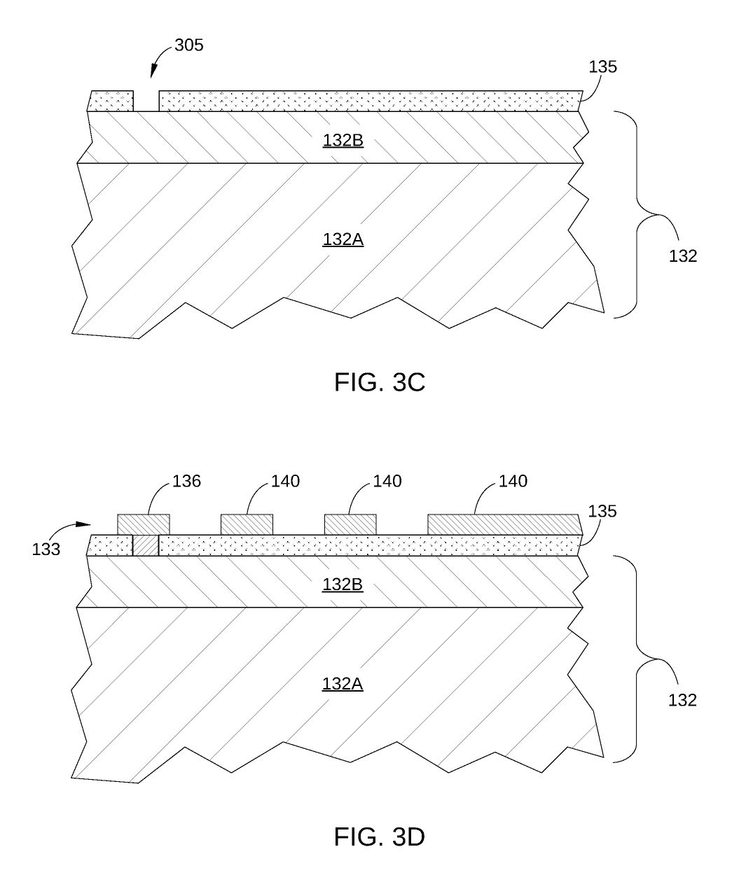

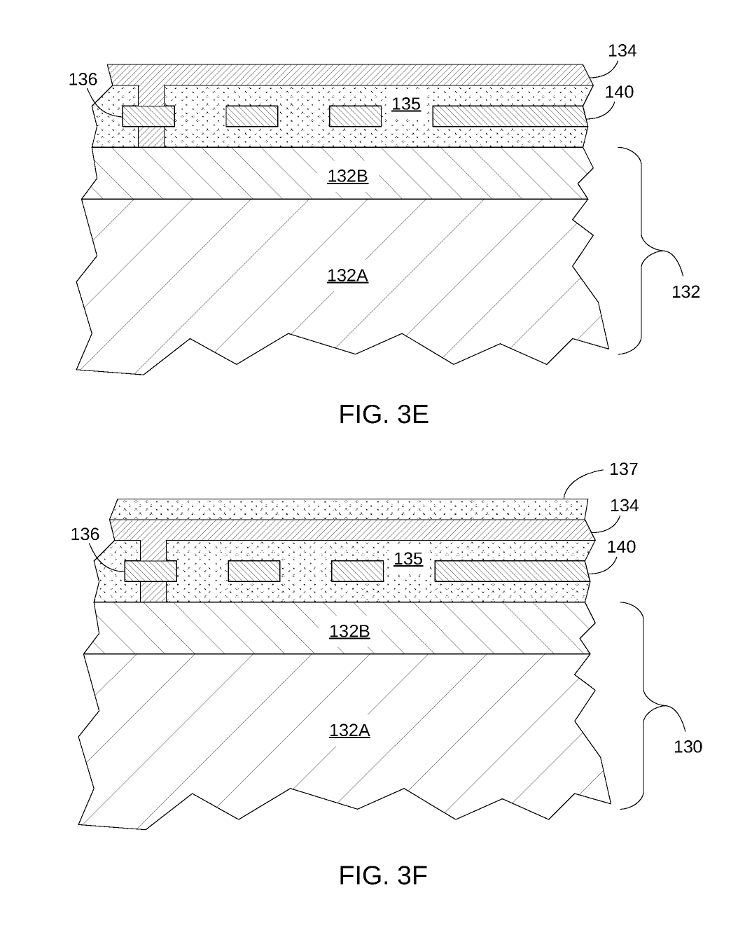

FIGS. 3A-3F sequentially illustrate cross-sectional views of the integrated circuit system in FIG. 1 in various stages of fabrication, according to embodiments of the invention. FIG. 3A shows semiconductor substrate 312 after being prepared for processing. Semiconductor substrate 312 includes bulk region 312A, which is a lightly doped P-type or N-type semiconductor material.

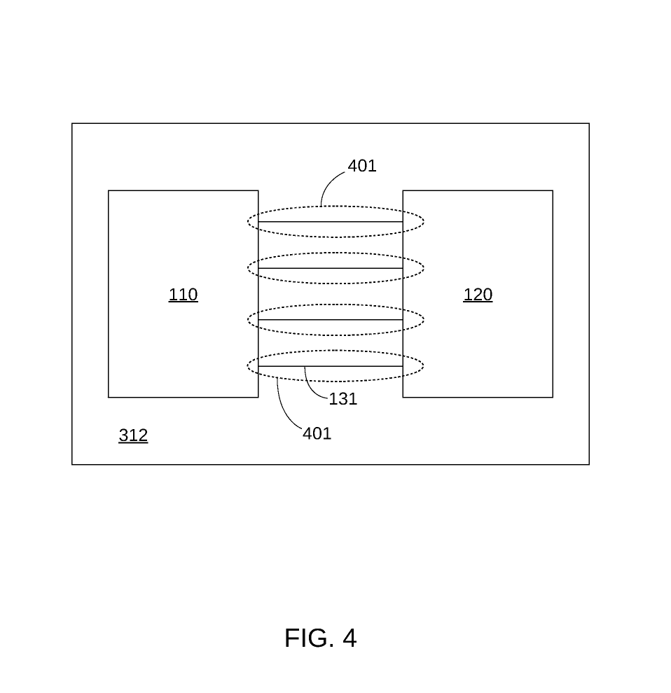

FIG. 3B depicts semiconductor substrate 312 after the formation of surface region 312B. As shown, surface region 312B is formed on a surface of bulk region 312A. In one embodiment, region 312B is formed via an ion-implantation process 301. In other embodiments, region 312B may be formed by a deposition process, such as chemical vapor deposition (CVD). In either case, a depth 302 and ion concentration of surface region 312B may be selected so that surface region 312B functions as a ground plane when electrically coupled to ground for IC system 100. In some embodiments, ion-implantation process 301 comprises a blanket implantation process, in which substantially the entire surface of semiconductor substrate 312 is implanted with suitable dopant ions. In other embodiments, using masking and patterning techniques commonly known in the art, selected regions 401 of the surface of semiconductor substrate 312 are implanted with dopant ions, as described below in conjunction with FIG. 4.

FIG. 3C shows semiconductor substrate 312 after the formation, patterning, and etching of electrically insulating layer 135 on surface region 312B. The patterning process forms one or more apertures 305 in electrically insulating layer 135 that expose a portion of surface region 312B. Consequently, contact structure 136 (shown in FIG. 2) can be formed to electrically couple surface region 3128 to subsequently formed ground plane 134 (also shown in FIG. 2). Various techniques known in the art may be used to produce electrically insulating layer 135 and aperture 305 as depicted in FIG. 3C.

FIG. 3D shows semiconductor substrate 312 after signal interconnects 140 and portions of contact structure 136 are formed. In some embodiments, aperture 305 in FIG. 3C is filled and signal layer 133 is formed in a single metal deposition process, such as copper electro-plating. In other embodiments, aperture 305 is filled in a first deposition process, such as CVD-tungsten deposition, and signal layer 133 is formed in a second deposition process, such as electroplating. Signal layer 133 is then patterned and etched to form signal interconnects 140 as shown. Signal interconnects 140 may include interconnects 131 in FIG. 1 as well as other input/output connections to and from ICs mounted on interposer substrate 130.

FIG. 3E shows semiconductor substrate 312 after the formation of additional electrically insulating layers 135 and ground plane 134, using the previously described techniques and/or other deposition, patterning, and etching techniques known in the art. In some embodiments, ground plane 134 is deposited and contact structure 136 is completed in a single metal deposition process, such as an electroplating process. In other embodiments, the final portion of contact structure 136 is deposited in a separate metal deposition process from the deposition of ground plane 134. In either case, contact structure 136 electrically couples ground plane 134 to surface region 312B.

FIG. 3F shows semiconductor substrate 312 after the formation of passivation layer 137 on ground plane 134. Passivation layer 137 includes an electrically insulating material and can be readily formed using various techniques known in the art. Passivation layer 137 electrically isolates and mechanically protects ground plane 134.

As noted above, in some embodiments, selected regions 401 of the surface of semiconductor substrate 312 are implanted with dopant ions rather than substantially the entire surface thereof. Masking and patterning techniques commonly known in the art may be used to effect such patterned doping of semiconductor substrate 312. FIG. 4 schematically illustrates a plan view of IC system 100, according to one embodiment of the invention. As shown, selected regions 401 are disposed on portions of semiconductor substrate 312 that correspond to the location of interconnects 131. Regions 401 may also be disposed on portions of semiconductor substrate 312 that correspond to the positions of any other interconnects in signal layer 133, such as signal interconnects 140 in FIG. 2. Although regions 401 are formed on semiconductor substrate 312 prior to the formation of interconnects 131 and the mounting of first IC 110 and second IC 120, interconnects 131, first IC 110, and second IC 120 are shown in FIG. 4 for reference.

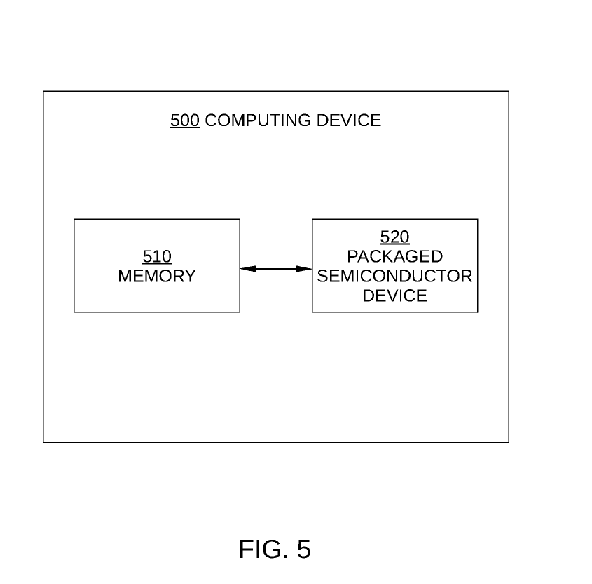

FIG. 5 illustrates a computing device 500 in which one or more embodiments of the present invention can be implemented. As shown, computer system 500 includes a memory 510 and a packaged semiconductor device 520 that is coupled to memory 510 and may be configured according to one or more of the embodiments of the present invention. Computer system 500 may be a desktop computer, a laptop computer, a smartphone, a digital tablet, a personal digital assistant, or other technically feasible computing device. Memory 510 may include volatile, non-volatile, and/or removable memory elements, such as random access memory (RAM), read-only memory (ROM), a magnetic or optical hard disk drive, a flash memory drive, and the like. Packaged semiconductor device 520 may be substantially similar in configuration and operation to IC system 100 described above in conjunction with FIGS. 1 and 2, and may comprise a CPU, a GPU, an application processor or other logic device, or any other IC chip-containing device.

In sum, embodiments of the invention set forth an integrated circuit system that includes an interposer substrate with an electrical reference plane, or “ground plane,” formed by a conductive semiconductor layer. The conductive semiconductor layer may be formed in a surface region of the interposer substrate, and in some embodiments is formed by performing an ion implant process on the surface region to increase the electrical conductivity of the surface region. Advantageously, one of the ground planes on the interposer substrate can be formed without depositing a metalization layer, thereby greatly simplifying the fabrication process.

While the foregoing is directed to embodiments of the present invention, other and further embodiments of the invention may be devised without departing from the basic scope thereof, and the scope thereof is determined by the claims that follow.

1. A semiconductor-based system, comprising:
an interposer substrate that includes:
a semiconductor substrate having a bulk region and a surface region that is more heavily doped than the bulk region, the surface region forming a first ground plane,
an electrical interconnect layer formed on the surface region, and
a second ground plane that is formed on the electrical interconnect layer and electrically coupled to the surface region; and
at least one semiconductor die mounted on the interposer substrate.

2. The system of claim 1, wherein the second ground plane and surface region are electrically coupled to an electrical ground of the semiconductor-based system.

3. The system of claim 1, wherein the bulk region has an ion concentration of no greater than about 10¹³ ions/cm³.

4. The system of claim 1, wherein the surface region has an ion concentration of at least about 10¹⁴ ions/cm³.

5. The system of claim 1, wherein the surface region has a sheet resistance that is no greater than about 200 ohm/sq.

6. The system of claim 1, wherein the bulk region has an electrical resistivity that is between about 5 ohm-cm and about 100 ohm-cm.

7. The system of claim 1, wherein the at least one semiconductor die comprises a logic die and a memory die, and the electrical interconnect layer includes electrical traces that electrically couple the logic die to the memory die.

8. The system of claim 7, wherein the surface region is disposed in selected regions on the interposer substrate where the electrical traces are formed and not in selected regions of the interposer substrate where the electrical traces are not formed.

9. The system of claim 1, wherein the surface region is doped by way of an ion implant process.

10. The system of claim 1, wherein the first semiconductor type comprises one of an n-type semiconductor and a p-type semiconductor.

11. A computing device, comprising:
a memory; and
a packaged semiconductor device coupled to the memory, wherein the packaged semiconductor device comprises:
an interposer substrate having,
a semiconductor substrate having a bulk region and a surface region that is more heavily doped than the bulk region, the surface region forming a first ground plane,
an electrical interconnect layer formed on the surface region, and
a second ground plane that is formed on the electrical interconnect layer and electrically coupled to the surface region; and
at least one semiconductor die mounted on the interposer substrate.

12. The computing device of claim 11, wherein the second ground plane and surface region are electrically coupled to an electrical ground of the semiconductor-based system.

13. The computing device of claim 11, wherein the bulk region has an ion concentration of no greater than about 10¹³ ions/cm³.

14. The computing device of claim 11, wherein the more heavily doped surface region has an ion concentration of at least about 10¹⁴ ions/cm³.

15. The computing device of claim 11, wherein the surface region has a sheet resistance that is no greater than about 200 ohm/sq.

16. The computing device of claim 11, wherein the bulk region has an electrical resistivity that is between about 5 ohm-cm and about 100 ohm-cm.

17. The computing device of claim 11, wherein the at least one semiconductor die comprises a logic die or a memory die, and the electrical interconnect layer includes electrical traces that electrically couple the logic die to the memory die.

18. The computing device of claim 17, wherein the surface region is disposed in selected regions on the interposer substrate where the electrical traces are formed and not in selected regions of the interposer substrate where the electrical traces are not formed.

19. The computing device of claim 11, wherein the surface region is doped by way of an ion implant process.

20. The computing device of claim 11, wherein the first semiconductor type comprises one of an n-type semiconductor and a p-type semiconductor.
